(19) United States
(12) Patent Application Publication
(10) Pub. No.: US 2026/0223480 A1
(43) Pub. Date: Jul. 30, 2026

(54) BACKSIDE-CONTACT SOLAR CELL AND METHOD FOR PRODUCING A BACKSIDE-CONTACT SOLAR CELL

(71) Applicant: Erik HOFFMANN, Stuttgart (DE)

(72) Inventor: Erik HOFFMANN, Stuttgart (DE)

(73) Assignee: Silfab Solar Cells SC Inc., Fort Mill, SC (US)

(21) Appl. No.: 19/457,184

(22) Filed: Jan. 23, 2026

(30) Foreign Application Priority Data
Jan. 23, 2025 (DE) 10 2025 102 363.8

(51) Int. Cl. H10F 77/20; H10F 10/14; H10F 71/10; H10F 77/122; H10F 77/14; H10F 77/30

(52) U.S. Cl. CPC H10F 77/219; H10F 10/14; H10F 71/103; H10F 77/122; H10F 77/147; H10F 77/311

(57) ABSTRACT

A back-contact solar cell and a method for producing the same are disclosed. The solar cell back side includes first, second and third areas. The first areas are on pedestal-like elevations, each having first and second conducting layers and a first tunneling layer between the first conducting layer and the semiconductor substrate. The first and second conducting layers are each amorphous, polycrystalline or partially crystalline. Each second area has the second conducting layer and a second tunneling layer between the second conducting layer and the semiconductor substrate. The third areas do not contain amorphous, polycrystalline or partially crystalline silicon. A first dielectric layer or stack including first and second interruptions respectively in the first and second areas at least partially covers the back side. First and second electrodes respectively contact the first and second conducting layers in the first and second areas through corresponding first and second interruptions.

### CROSS-REFERENCE TO RELATED APPLICATIONS

This application claims priority to German Pat. Appl. No. 10 2025 102 363.8, filed on Jan. 23, 2025, the contents of which are incorporated by reference herein in its entirety.

### FIELD OF THE INVENTION

The invention relates to a back-contact solar cell with features as described herein and a method for producing a back-contact solar cell with such features.

### DISCUSSION OF THE BACKGROUND

In a back-contact solar cell, electrodes of opposite polarities, as well as emitter regions and base regions, are arranged on the back of the solar cell. The back of the solar cell is the side facing away from the sun during the operation of the solar cell. Accordingly, the front of the solar cell is the side facing the sun.

Back-contact solar cells can generally achieve a higher efficiency than solar cells in which electrodes of one polarity are on the front side and electrodes of the opposite polarity are on the back side. In back-contact solar cells, the front side is not shaded by electrodes. To minimize resistance and recombination losses in back-contact solar cells, the electrodes of both polarities, as well as the emitter and base regions, are arranged alternately on the back side, with a small gap between the different regions.

The generation of a variety of p-n junctions with small spacing is technically significantly more challenging than, for example, a conventional solar cell with a large-area, bilateral contact p-n junction. The alternately arranged emitter and base regions on the back side can be realized, for instance, using laser irradiation. In this process, n-type and p-type dopants are locally introduced into a semiconductor substrate by temporally and spatially separated melting of the surface with laser irradiation, thereby creating either a p-type or n-type doped region depending on the dopant. Such a laser doping method is disclosed, for example, in DE 10 2013 219 564 A1. The described structuring of the back side allows for efficiencies of up to 24% due to low internal series resistances and high current yields.

Even higher efficiencies are essentially limited by recombination mechanisms in the base as well as on the heavily-doped contact and non-contact surfaces. Recombination in the base depends on the quality of the semiconductor substrate, and can only be influenced to a limited extent in the manufacturing process of the solar cell. Recombination mechanisms at the doped n-type and p-type surfaces are limited in the non-contact areas by Auger recombination only when there is good surface passivation, with Auger recombination increasing with the dopant concentration in silicon. In contact areas, where metal electrodes contact silicon, the contact with the metal leads to high interface recombination. During the manufacturing process, Auger recombination at the non-contact surfaces can be reduced by minimizing doping. A high dopant concentration is advantageous at the contact surfaces, as this reduces contact resistance and interface recombination.

To address this discrepancy, the use of so-called passivating or charge carrier-selective contacts is known, as seen in, for example, DE 10 2013 219 564 A1 or WO 2014/100004 A1. The electrodes do not directly contact the crystalline silicon wafer, which serves as an absorber, but are separated by a thin dielectric layer, such as a silicon oxide layer. The silicon oxide layer passivates the silicon surface on one hand. On the other hand, the silicon oxide layer is so thin that charge carriers (particularly electrons) can tunnel through the silicon oxide layer from the semiconductor to the electrode, or from the electrode to the semiconductor (depending on the polarity). Therefore, the silicon oxide layer can be referred to as a tunneling layer through which charge carriers can tunnel. The tunneling layer may also have small holes, e.g., in the nanometer (nm) range, that can allow for current flow.

To induce charge carriers to tunnel, there can be an electric field present in or across the tunneling layer. The electric field can be generated, for example, by a heavily doped n- or p-type silicon layer above the tunneling layer. The doping of this heavily doped silicon layer above the tunneling layer leads to band bending in the silicon base beneath the tunneling layer. Therefore, classical doping of the silicon base to create a p-n junction is no longer necessary. Since the silicon base is no longer or only marginally doped, Auger recombination in the base decreases. The spatial separation of a metal/silicon interface of the electrodes from the silicon base also reduces surface recombination. Nevertheless, a low contact resistance can be achieved because the electrodes contact the heavily doped silicon layer. Doped silicon layers, for example, include amorphous, partially crystalline, or polycrystalline silicon layers with a thickness of 20 nm to 400 nm, which can be deposited using methods such as PECVD, LPCVD, APCVD, or PVD.

Back-contact solar cells with charge carrier-selective contacts of opposite polarities have so far achieved an efficiency of up to 26.7%. However, the production of such solar cells is very complicated, as the two differently doped passivating contacts have been made only using various complex masking and fabrication steps. High precision and fine resolution of the masking and fabrication have been necessary. The distance between the charge carrier-selective contacts of opposite polarities should not exceed the diffusion length of the free charge carriers. However, large distances can also lead to an increase in internal series resistance due to lateral current flow in the base.

The differently-doped silicon layers of the charge carrier-selective contacts can also be separated either by an undoped silicon layer or by a spatial separation (e.g., a trench or a break). Without such separation, the transition between the differently-doped layers has a defect-rich p-n junction, which limits the efficiency of the solar cell. Ideally, the separation should be as fine as possible, as a large area for separation can adversely affect the short-circuit current and the open-circuit voltage.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

It is therefore an object of the present invention to provide a rear contact solar cell and a method for manufacturing a rear contact solar cell, whereby the solar cell has a high efficiency and can be produced cost-effectively and efficiently.

This object is provided by a back-contact solar cell that comprises a semiconductor substrate, a front side, and a back side. The semiconductor substrate may include silicon or be formed from silicon. A plurality of first areas, a plurality of second areas, and a plurality of third areas are on the back side of the solar cell. The first areas each comprise a stack including a first conductive layer and a second conductive layer. The second areas each comprise the second conductive layer. The first conductive layer and/or the second conductive layer may include a dopant. The first conductive layer and/or the second conductive layer may, for example, include a silicon layer, a silicon carbide layer, a conductive metal oxide layer, and/or a conductive layer stack. The dopant in the first conductive layer and the dopant in the second conductive layer may have different or opposing polarities. The first conductive layer and the second conductive layer can each be amorphous, partially crystalline, or polycrystalline. The third areas are not amorphous, partially crystalline, or polycrystalline. More specifically, the third areas may be without amorphous, partially crystalline, or polycrystalline silicon. The first areas and the second areas comprise passivating contacts. In the first areas, a first tunneling layer is between each of the first conductive layers and the semiconductor substrate. In the second areas, a second tunneling layer is between each of the second conductive layers and the semiconductor substrate.

In particular, in the first area, a first electrode contacts the second conductive layer through a first interruption, and in the second area, a second electrode contacts the second conductive layer through a second interruption.

The first areas are on pedestal-like elevations of the semiconductor substrate. The elevations each have a cross-section that expands at least partially, and more preferably completely, in a first direction. In particular, the shape of the cross-section of the pedestal-like elevations can be trapezoidal. This allows the third areas to be in a retracted or undercut area that expands transversely to the first direction, and thus quasi in the “shadow” (in relation to the first direction) of the first areas. The first conductive layers and the second conductive layers, especially in the first and second areas, are therefore each separated from one another by the third areas. The third areas may form or include a step in the “shadow” of the first areas. As a result, separate charge carrier-selective contacts with a fine separation of just a few micrometers and a high resolution can be implemented without further elaborate structuring steps. This separation can avoid a p-n junction in both conductive layers, which can limit the fill factor and thus the efficiency. A solar cell with the highest possible efficiency and that is cost-effective and efficient to manufacture can therefore be produced.

The first direction may refer to a direction pointing away from the back of the solar cell. It is also conceivable that the first direction can be a direction pointing towards the back of the solar cell. The first direction is, more particularly, perpendicular to the front and back of the solar cell.

The first conductive layers can be p-type or n-type (or positive type or negative type) layers. The second conductive layers can also be p-type or n-type layers. The first conductive layers and the second conductive layers are amorphous, partially crystalline, or polycrystalline, and thus, can differ from the semiconductor substrate (or silicon base), which may be crystalline, especially monocrystalline.

The expanding cross-section of the pedestal-like elevations can be implemented at least partially, and more preferably completely, by undercuts (see the detailed discussion below). This allows for the formation of third areas that extend transversely to the first direction in a range of 0.5 μm to 20 μm (micrometers), and more preferably in a range of 1 μm to 10 μm, where there is no (amorphous, partially crystalline or polycrystalline) conductive layer.

The first conductive layer can be a doped silicon layer. The second conductive layer can also be a doped silicon layer. The first tunneling layer can be a passivation layer. The first tunneling layer can serve to passivate (e.g., the underlying semiconductor substrate) or be used for passivation. The first and/or second tunneling layers can be or comprise a dielectric layer, such as a silicon oxide (e.g., SiOₓ, where x is 2 or close to 2) or a silicon oxynitride (SiON; e.g., SiOₓN_{y}, where x is between 0 and 2 and y is [4−2x]/3), and/or a (thin) intrinsic (non-conductive) layer, such as amorphous silicon.

The second tunneling layer can be a passivation layer or have a passivating effect. The second tunneling layer can serve for passivation.

According to further embodiments of the solar cell, the third areas can be undercut areas. This allows the third areas to be implemented simply.

The second areas may be formed freely without undercuts. In other words, the second areas are not specifically undercut areas.

According to a further embodiment of the solar cell, the third areas can be undoped. In this context, “undoped” refers to no additional (process-related) doping. An undoped layer exhibits the same doping (type and concentration) as the semiconductor substrate. The semiconductor substrate can have a low doping, for example, in the range of 5×10¹⁶ cm⁻³. Thus, an “undoped” layer can also exhibit the same low doping. Accordingly, “doping” refers to additional doping relative to the semiconductor substrate. When an intrinsic amorphous silicon layer is implemented as a passivation layer and/or as a tunneling layer, it may differ from the semiconductor substrate, in particular from the “undoped” silicon of the semiconductor substrate. This allows the third areas to be implemented simply. In particular, this allows for a clear (unallocated) separation between the first and/or second conductive layers.

According to further embodiments, the third areas can have a third conductive layer. The surface of the semiconductor substrate in the area of the third areas can therefore be doped. The third conductive layer can be a doped silicon layer. This allows for the efficiency of the solar cell to be further improved.

According to a further development of the solar cell, a fourth conductive layer may be on or in the front side of the solar cell. The fourth conductive layer may be or comprise a doped silicon layer. This can further improve the efficiency of the solar cell.

According to an even further development of the solar cell, the semiconductor substrate, the first conductive layers, the second conductive layers, the third conductive layers, the fourth conductive layer and/or the third areas may have a doping according to one of the combinations in Table 1 below:

TABLE 1

| | | | Third area or | Front side or |
|---|---|---|---|---|
| | First | Second | third | fourth |
| Semiconductor | conductive | conductive | conductive | conductive |
| substrate | layer | layer | layer | layer |
| n | n | p | — | p |
| n | n | p | — | n |
| n | n | p | p | p |
| n | n | p | n | n |
| n | p | n | — | p |
| n | p | n | — | n |
| n | p | n | p | p |
| n | p | n | n | n |
| p | n | p | — | p |
| p | n | p | — | n |
| p | n | p | p | p |
| p | n | p | n | n |
| p | p | n | — | p |
| p | p | n | — | n |
| p | p | n | p | p |
| p | p | n | n | n |
| p | n | p | — | — |
| p | n | p | — | — |
| p | n | p | p | — |
| p | n | p | n | — |
| p | p | n | — | — |
| p | p | n | — | — |
| p | p | n | p | — |
| p | p | n | n | — |
| n | n | p | — | — |
| n | n | p | — | — |
| n | n | p | p | — |
| n | n | p | n | — |
| n | p | n | — | — |
| n | p | n | — | — |
| n | p | n | p | — |
| n | p | n | n | — |

In this context, and especially in Table 1, “p” refers to an additional p-type or positive doping compared to the semiconductor substrate, “n” refers to an additional n-type or negative doping compared to the semiconductor substrate, and “−” means no additional doping compared to the semiconductor substrate. This allows the solar cell to be designed and implemented as flexibly as possible.

According to a further embodiment of the solar cell, the first conductive layers, the second conductive layers, the first tunneling layers and/or the second tunneling layers can each be free of breakthroughs. The first and/or second tunneling layers can each be closed or continuous layers. In particular, the first tunneling layers and/or the second tunneling layers are not or only slightly broken through (e.g., penetrated) by the first electrodes and/or the second electrodes. This can further improve the efficiency of the solar cell.

According to another embodiment of the solar cell, the second conductive layers and/or the second tunneling layers can each be penetrated by an aluminum-silicon eutectic. The aluminum-silicon eutectic can also be at or under respective first and/or second electrodes. This can further improve the efficiency of the solar cell.

According to another advancement in the present solar cells, the aluminum-silicon eutectic can be at least partially surrounded by a fifth conductive layer. The fifth conductive layer can be a doped silicon layer. The fifth conductive layer can have a p-type doping, for example an aluminum doping, or an n-type doping. If an aluminum-silicon eutectic is at the first electrodes and/or the second electrodes, the respective fifth conductive layer can have a polarity that corresponds to the polarity of the respective electrode(s). In particular, the fifth conductive layers at least partially surrounding the eutectics at the first electrodes and the fifth conductive layers at least partially surrounding the eutectics at the second electrodes can have opposite polarities. This can further improve the efficiency of the solar cell. In addition, production can be implemented more cost-effectively.

The above structures may be provided by a process for producing a rear-contact solar cell according to one or more of the descriptions herein. The process includes the steps:

Providing a semiconductor substrate having a front side and a back side.

Forming a first tunneling layer, for example, a dielectric layer or an intrinsic amorphous silicon layer, on the back of the semiconductor substrate.

Forming a first conductive layer, in particular a doped silicon layer, having a first polarity on the first tunneling layer. More particularly, when the first conductive layer is doped ex-situ, an undoped layer can initially be deposited and then doped. This can be implemented, for example, in a furnace diffusion process. A silicate layer may form during this process, which can also serve as an etch barrier layer.

Forming an etch-stable barrier layer on the first conductive layer.

Removing the etch-stable barrier layer in a plurality of etching areas.

Etching, in particular the first conductive layer, the first tunneling layer, and the surface of the semiconductor substrate, in the etching areas, to produce pedestal-like elevations in the semiconductor substrate with a cross-section that widens at least partially, and more preferably completely, in a first direction. The pedestal-like elevations thus extend out of the semiconductor substrate. The etching can include underetching, particularly below peripheral edges or regions of the etch-stable barrier layer, and may comprise wet chemical etching. In further embodiments, the method further comprises completely removing the etch-stable barrier layer (e.g., after forming the pedestal-like elevations).

Forming a second tunneling layer, and more preferably in the areas between the pedestal-like elevations of the semiconductor substrate, in the first areas and/or in the second areas.

Forming a second conductive layer, in particular a doped silicon layer, with a second polarity opposite to the first polarity, and more preferably in the second areas (e.g., between the pedestal-like elevations), where due to the decreasing cross-section of the pedestal-like elevations and the increasing width of the third areas, the second conductive layer is not formed. Thus, the third areas are not amorphous, semi-crystalline, or polycrystalline. In particular, the third areas contain no amorphous, semi-crystalline, or polycrystalline silicon.

Regarding the advantages that can be achieved with the process, reference is made to the relevant explanations concerning the solar cell. For further elaboration of the process, the measures described in connection with the solar cell and/or those explained below can be used. According to one or more further embodiments of the process, the method may further comprise forming third conductive layers, in particular doped silicon layers, in the third areas and/or forming a fourth conductive layer, in particular a doped silicon layer, in, at or on the front side using furnace diffusion.

According to a further development of the method, the method may further include removing a silicate glass layer formed during the furnace diffusion, for example a phosphosilicate glass or a borosilicate glass, in particular by etching (e.g., wet chemical etching).

According to a further development of the method, the method may further include forming first and/or second electrodes and/or forming an aluminum-silicon eutectic at the second electrodes using one or more pastes or paste stacks, in particular where the paste(s) or paste stack(s) contain a p-type dopant, in particular aluminum, and/or an n-type dopant.

The process particularly includes an anisotropic or isotropic wet chemical etching of the first conductive layer, the first tunneling layer, and/or the semiconductor substrate. The wet chemical etching can be performed after the deposition or growth of the first tunneling layer, the first conductive layer, the deposition of an etch barrier layer, and the patterning of the etch barrier layer, for example, by laser irradiation. The wet chemical etching can remove approximately 0.5 μm to 20 μm, and more preferably 1 μm to 10 μm, of silicon along the first direction (e.g., an etch depth perpendicular to the surface). This also results, regardless of whether the etching is performed anisotropically or isotropically, in underetching of the etch barrier and possibly the first conductive layer (e.g., if it has a high etch stability due to its chemical properties).

Subsequently, the etch barrier layer can be removed.

After growing a second tunneling layer, which passivates the exposed surface of the semiconductor substrate (e.g., after etching to form the pedestal-like elevations), the second conductive layer can be deposited, for example, by physical vapor deposition (PVD). Unlike conventional chemical vapor deposition methods (such as PECVD, LPCVD, APCVD), hardly any material is deposited (e.g., grows or precipitates) transversely to the first direction (i.e., on surfaces perpendicular to the deposition direction of the material). In particular, no material is deposited in the undercut areas (i.e., the third areas). Thus, third areas can be formed that have neither the first conductive layer nor the second conductive layer therein. The p-n junction can therefore exist exclusively in the semiconductor substrate (silicon wafer) and thus exhibit low recombination activity. This enables a high fill factor and high efficiency to be achieved.

In other words, when removing the first conductive layer through chemical etching in areas without a barrier layer, isotropic or anisotropic undercutting of the barrier layer occurs. The deposition of the second conductive layer can be implemented by a physical, directed, unidirectional gas-phase deposition. As a result, the second conductive layer is not deposited on all exposed surfaces on the back of the solar cell, but is at least interrupted in the shaded areas of the undercutting. Therefore, no additional process step is required for the separation of the first conductive layer in the first areas and the second conductive layer in the second areas. Furthermore, this separation (i.e., areas without the first and second conductive layers) extends over a width of a few micrometers (the sum of the etch depth and the undercut area). This allows for an ultra-fine separation of charge carrier-selective contacts in the micrometer range.

### BRIEF DESCRIPTION OF THE DRAWINGS

Further features, details, and advantages of the invention appear from the wording of the claims as well as from the following description of embodiments with reference to the drawings, which show:

FIG. 1 is a schematic cross-section of a back-contact solar cell according to a first embodiment;

FIG. 2 is a schematic cross-section of the back-contact solar cell according to a second embodiment;

FIG. 3 is a schematic cross-section of the back-contact solar cell according to a third embodiment;

FIG. 4 is a scanning electron image of a first, second, and third area of the solar cell according to the depictions of FIGS. 1 to 3;

FIGS. 5 to 16 show a method for manufacturing a back-contact solar cell according to a first embodiment; and

FIGS. 17 to 28 show a method for manufacturing a back-contact solar cell according to a second embodiment.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention. Furthermore, it should be understood that the possible permutations and combinations described herein are not meant to limit the invention. Specifically, variations that are not inconsistent may be mixed and matched as desired.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

In the following description and in the figures, corresponding components and elements are marked with the same reference signs. For better clarity, not all reference signs are shown in every figure.

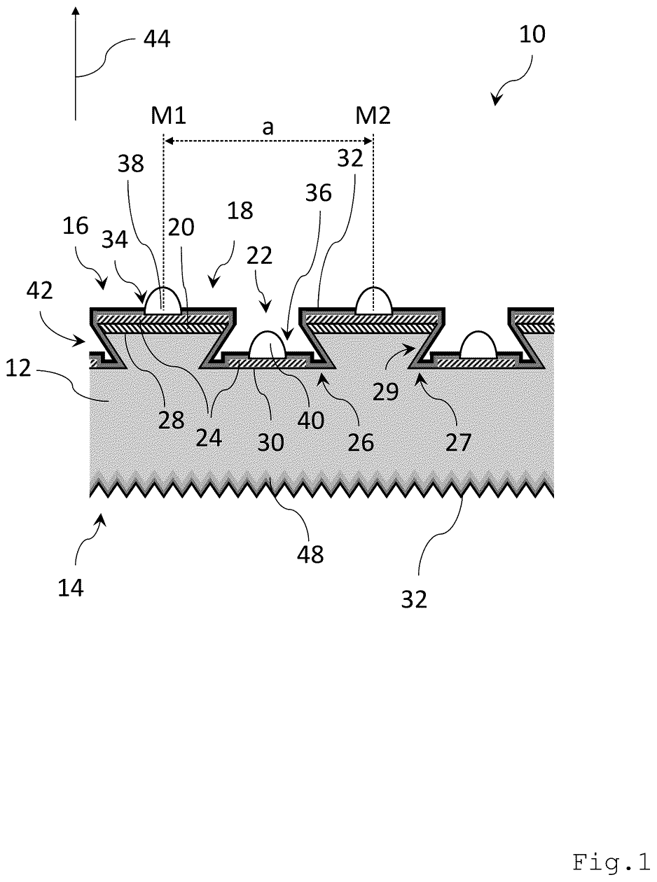

FIG. 1 shows a schematic cross-section of a rear-contact solar cell 10 according to a first embodiment. The solar cell 10 in this embodiment includes a crystalline n-type semiconductor substrate 12. The semiconductor substrate 12 forms a silicon base 12. This serves as an absorber. In another embodiment, it could also be a crystalline p-type silicon base 12.

The solar cell 10 has a front side 14 and a back side 16. The front side 14 is oriented towards the sun during the operation of the solar cell 10. In the embodiment illustrated in FIG. 1, the front side 14 is textured. On the back side 16 of the solar cell 10, there are a plurality of first areas 18, each with a stack including a first conductive layer 20 and a second conductive layer 24, a plurality of second areas 22 each with the second conductive layer 24, and a plurality of third areas 26. In the first areas 18, the second conductive layer 24 is above the first conductive layer 20.

The first conductive layers 20 and the second conductive layers 24 can each be amorphous, partially crystalline, or polycrystalline. They thereby specifically differ from the (mono)crystalline silicon base 12 (or the semiconductor substrate 12). The third areas 26 are not amorphous, partially crystalline, or polycrystalline. The third areas 26 do not contain any amorphous, partially crystalline, or polycrystalline silicon. A first tunneling layer 28 is between the first conductive layer 20 and the semiconductor substrate 12 (e.g., in the first areas 18). A second tunneling layer 30 is between the second conductive layer 24 and the semiconductor substrate 12 (e.g., in the second areas 22).

The first areas 18 and the second areas 22 may each be designed as passivating contacts. In this case, the back side 16 and the front side 14 (e.g., the outermost surfaces thereof) of the solar cell 10 are each at least partially, and preferably fully, covered with a dielectric layer 32. The dielectric layer 32 may comprise a stack of two dielectric different layers. The dielectric layer 32 can passivate the front side 14 and/or back side 16, reduce reflections at the front side 14, and improve the light absorption of the solar cell 10. The dielectric layer 32 may include, for example, aluminum oxide (AlOₓ), silicon oxide (SiOₓ), or silicon nitride (SiNₓ). The dielectric layer 32 may be a layer stack (i.e., made up of multiple layers). The layer stack may consist of two or more layers, including, for example, AlOₓ, SiOₓ, and/or SiNₓ. Other layers for reducing reflection and/or improving passivation are also conceivable. The dielectric layer 32 or layer stack on the front side 14 and the dielectric layer 32 or layer stack on the back side 16 can be identical or different in structure.

The dielectric layer 32 may have a first interruption 34 in the first areas 18 and a second interruption 36 in the second areas 22.

The solar cell 10 comprises a plurality of first electrodes 38 and a plurality of second electrodes 40. Each first electrode 38 contacts a second conductive layer 24, in this case through a first opening 34. It is also conceivable that the second conductive layer 24 could represent a (further) tunneling connection in the area of the first opening 34. Each second electrode 40 contacts a second conductive layer 24, in this case through the second opening 36. The first areas 18 are on pedestal-like projections 42 of the semiconductor substrate 12. The projections 42 each have a cross-section that expands at least partially, and more preferably completely, in a first direction 44. In other words, the cross-section of the projections 42 narrows opposite to the first direction 44. In the present case, the first direction 44 is a direction pointing away from the back side 16 of the solar cell. It is also conceivable that the first direction 44 may point towards the back side 16 of the solar cell.

The first conductive layer 20 may be a doped silicon layer. The second conductive layer 24 may also be a doped silicon layer. The third areas 26 may be undercut areas. The third areas 26 may be undoped.

In the example, the front side 14 includes a fourth conductive layer 48. The fourth conductive layer 48 can be a doped silicon layer. This can include p-type doped silicon. The fourth conductive layer 48 can form a so-called “Front Floating Emitter” (FFE), an emitter with a p-n junction, that is, with the opposite doping to the silicon base 12 or the semiconductor substrate 12. The fourth conductive layer 48 may be doped with a p-type dopant, for example boron, in particular with a dopant concentration of about 5×10¹⁷ cm⁻³ to 1×10²⁰ cm⁻³, preferably about 5×10¹⁸ cm⁻³ to 5×10¹⁹ cm⁻³.

In another embodiment, the fourth conductive layer 48 may have an n-type doping, preferably with a comparable or identical dopant concentration as for the p-type doped fourth conductive layer 48. In this case, the doping is referred to as a “Front Surface Field” (FSF) on the front side, meaning it may have the same doping type as the silicon base 12, but a greater doping concentration than the silicon base 12. The fourth conductive layer 48 can be doped with an n-type dopant, such as phosphorus, preferably with a dopant concentration of about 5×10¹⁷ cm⁻³ to 1×10²⁰ cm⁻³, and more preferably about 5×10¹⁸ cm⁻³ to 5×10¹⁹ cm⁻³.

The back 16 can, for example, be textured over the entire surface or planar (e.g., chemically polished) over the entire surface. The surface of the back 16 can also include a combination of textured areas and planar/polished areas. For example, the back surface can be polished in the first areas 18 and textured in the second areas 22 (or vice versa). Chemical polishing may comprise an anisotropic silicon etch, for example, with hot potassium hydroxide.

The first conductive layers 20 can comprise n-type doped polycrystalline silicon. The second conductive layers 24 can comprise p-type doped polycrystalline silicon. In this case, a second conductive layer 24 is in each of the first areas 18, above the first conductive layer 20 (with respect to the first direction 44).

In this case, the first areas 18 and the second areas 22 alternate. The distance a between a center M1 of a first (e.g., n-type doped) area 18 and a center M2 of the next first (e.g., also n-type doped) area 18 is, for example, between 300 μm and 3000 μm, preferably between 400 μm and 2000 μm. Accordingly, the distance between a center of a second (e.g., p-type doped) area 22 and a center of the next second (e.g., p-type doped) area is, for example, between 300 μm and 3000 μm, preferably between 400 μm and 2000 μm.

It is also conceivable that the doping of the first conductive layers 20 and the second conductive layers 24 could be reversed. That is, the first conductive layers 20 could comprise p-type doped silicon (which may be polycrystalline), and the second conductive layers 24 could comprise n-type doped silicon (which may also be polycrystalline).

Over the area of the back side 16 of the solar cell, the ratio of the total area of the p-type doped regions to the total area of the n-type doped regions is preferably between 1:9 to 9:1, more preferably 2:8 to 8:2, and even more preferably between 3:7 to 7:3.

The alternating pattern of the first and second areas 18, 20 can essentially extend completely or at least approximately over the entire back side 16 of the solar cell 10. However, the alternating pattern can also be interrupted locally, e.g. in areas where busbars are to be provided.

The layer thickness of the first conductive layers 20 and/or the second conductive layers 24 can be, for example, 20 nm to 400 nm. The first conductive layers 20 and the second conductive layers 24 can have the same layer thickness. It is also conceivable that the first conductive layers 20 and the second conductive layers 24 can have different layer thicknesses.

The first conductive layers 20 (or the second conductive layers 24) can be doped with an n-type dopant, e.g. phosphorus, at a dopant concentration of, for example, 1×10¹⁹ cm⁻³ to 3×10²¹ cm⁻³, preferably from 5×10¹⁹ cm⁻³ to 2×10²⁰ cm⁻³.

The first and/or second tunneling layers 28, 30 can each be a dielectric layer. The first and/or second tunneling layers 28, 30 can, for example, include a layer comprising silicon oxide (SiOₓ) or a layer comprising silicon oxynitride (SiOₓN_{y}), where x and y are as described herein. The first and/or second tunneling layers 28, 30 can passivate the surface of the semiconductor substrate 12 (or the silicon base 12). The first and/or second tunneling layers 28, 30 can, for example, have a thickness of 0.5 nm to 20 nm. This particularly enables tunneling of charge carriers.

The first and/or second tunneling layers 28, 30 can each be free of breakthroughs. It is also conceivable that the first and/or second tunneling layers 28, 30 may have openings, or so-called pinholes, having a width or diameter in the nanometer range (e.g., 0.1-10 nm, 1-9 nm, etc.). This allows ohmic contact to be made between the semiconductor substrate 12 (silicon base 12) and the first conductive layer 20 and/or the second conductive layer 24.

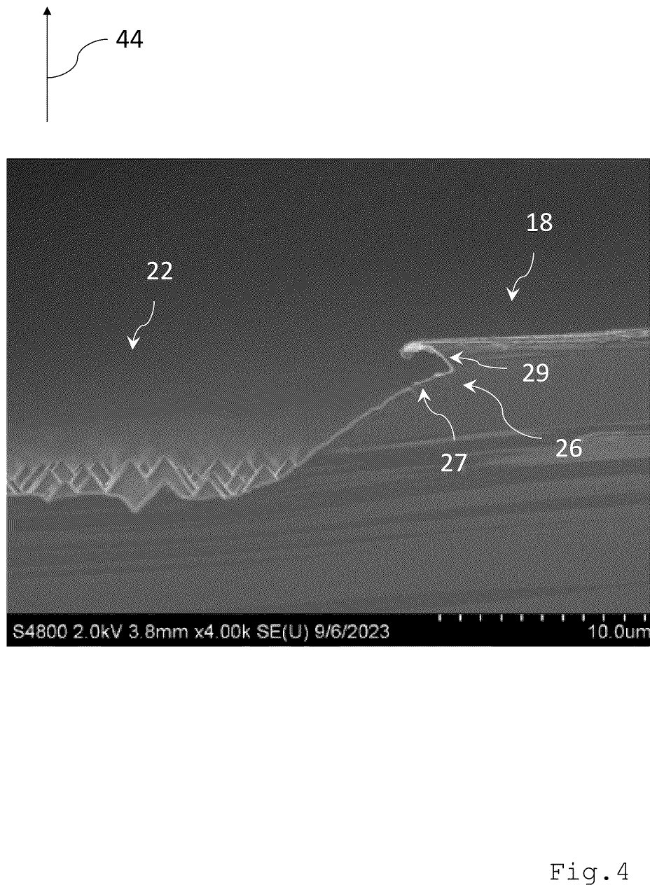

The first conductive layers 20, especially in the first areas 18, and the second conductive layers 24, especially in the second areas 22, are separated by the third areas 26. The third areas 26 are in a volume of undercut silicon in the semiconductor substrate 12 or the silicon base 12. The third areas 26 can include a first region 27 and a second region 29. The first region 27 can be oriented transversely (perpendicularly) to the first direction 44, while the second region 29 can be inclined or angled (e.g., at an angle between 0° and 90°, such as in the range of 5-45°) with respect to the first direction 44. It is also conceivable that both the first regions 27 and the second regions 29 can each be inclined or angled with respect to the first direction 44 (see FIG. 4).

In the third areas 26, there are preferably no (or only minimal) amounts of the second conductive layer 24. Thus, there is no p-n junction between the first conductive layers 20, especially the areas 18, and the second conductive layers 24, particularly the areas 22. In the illustrated first embodiment, the silicon base 12 (or the semiconductor substrate 12) contains no added dopant in the third areas 26. The dopant concentration of the third areas 26 may therefore correspond to the dopant concentration of the silicon base 12. The surface of the third areas 26 can be covered or passivated by a passivating layer, in particular by the second tunneling layer 30 (e.g., a dielectric or amorphous silicon layer). Additionally or alternatively, the surface of the third areas 26 can be covered with the dielectric layer 32 (or a dielectric layer stack). For this purpose, the dielectric layer 32 (or dielectric layer stack) can be formed non-directionally, in contrast to the second conductive layer 24, and can also include the third areas 26.

The dielectric layer 32 essentially serves to passivate the surface of the silicon base 12 (or the semiconductor substrate 12). On one hand, the dielectric layer 32 may be or provide a source of hydrogen to improve passivation with the first or second tunneling layers 28, 30; on the other hand, it can also saturate open bonds in the third areas 26 and enhance passivation through the field effect. The dielectric layer 32 may also be used to optimize the optical properties of the solar cell 10, especially when the solar cell 10 is used bifacially. The dielectric layer 32, for example, includes aluminum oxide (AlOₓ; e.g., Al₂O₃), silicon oxide (SiOₓ; e.g., SiO₂), and/or silicon nitride (SiNₓ; e.g., Si₃N₄). The dielectric layer 32 can consist of a stack of layers comprising at least two layers, for example, comprising AlOₓ, SiOₓ, and/or SiNₓ. Other layers for reducing reflection and/or improving passivation are also conceivable.

The dielectric layer 32 covers almost the entire surface of the back side 16 and the front side 14 in the embodiment shown in FIG. 1.

First and second interruptions 34, 36 are in the dielectric layer 32 on the back side 16. The first and second interruptions 34, 36 can, for example, be openings. These first and second interruptions 34, 36 allow for electrical contact between the respective second conductive layers 24 and the corresponding first and second electrodes 38, 40. In other words, the first and second electrodes 38, 40 contact the second conductive layers 24 through the first and second interruptions 34, 36.

The first and/or second interruptions 34, 36 can, for example, be continuous, round or square, or line-shaped or segmented. Accordingly-shaped contact surfaces for the first and second electrodes 38, 40 can be provided, for example, point-shaped or circular contact surfaces, or line-shaped or segmented contact surfaces.

The first electrodes 36 can be negative electrodes. The second electrodes 38 can be positive electrodes. It is also conceivable that the first electrodes 36 can be positive electrodes. It is likewise conceivable that the second electrodes 38 can be negative electrodes.

The first or second (negative or positive) electrodes 38, 40 can consist of one or more metals, for example, silver, copper, or aluminum. The first or second electrodes 38, 40 can, for example, be a stack of silver and copper layers to reduce or minimize the silver content of the metallization. In this context, the first tunneling layer 28 in the first area 18 and the second tunneling layer 30 in the second area 22 may be uninterrupted (a closed layer). It is also conceivable that the first and/or second tunneling layers 28, 30 in the areas of the first and second interruptions 34, 36 are interrupted.

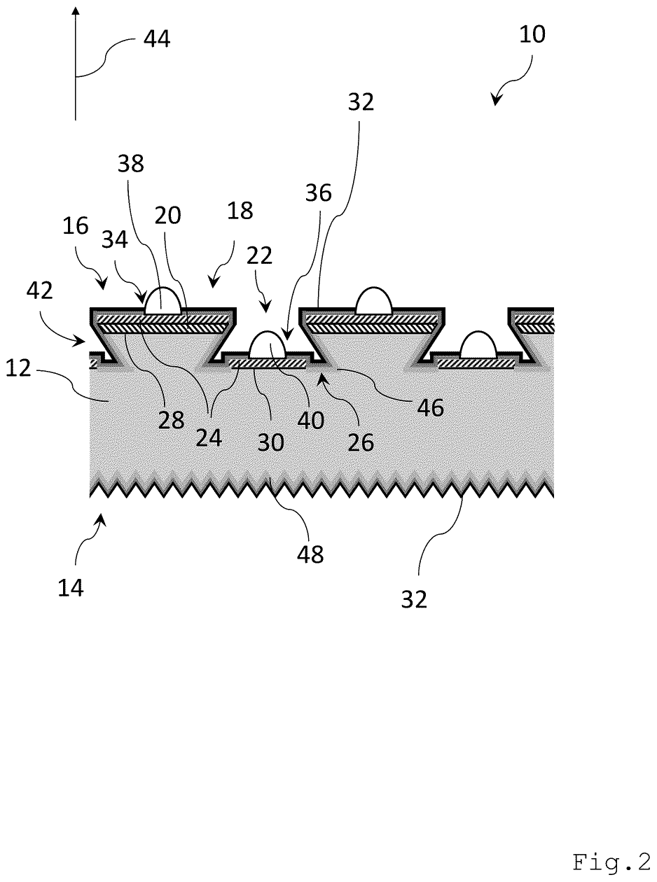

FIG. 2 shows a schematic cross-section of the rear-contact solar cell 10 according to a second embodiment. The second embodiment differs from the first embodiment shown in FIG. 1 in the following ways:

In particular, the surface of the semiconductor substrate 12 in the third areas 26 can be further doped, so that the doping concentration in the third areas 26 exceeds the doping concentration of the semiconductor substrate 12. The third areas 26 in FIG. 2 have a third conductive layer 46. The third conductive layer 46 can be a doped silicon layer. Furthermore, the second tunneling layer 30 is absent or has been removed in the third areas 26. The third conductive layer 46 can be doped, for example, with an n-type or p-type dopant. This additional doping (compared to the semiconductor substrate 12) can improve passivation in the third areas 26. Depending on the doping of the third conductive layer 46, a p-n junction may form with the first (e.g., p-type) conductive layer 20 or with the second (e.g., n-type) conductive layer 24. The third areas 26 may also include another conductive layer, similar to the second conductive layer 24, but significantly thinner or of high resistance, so that the efficiency is not affected.

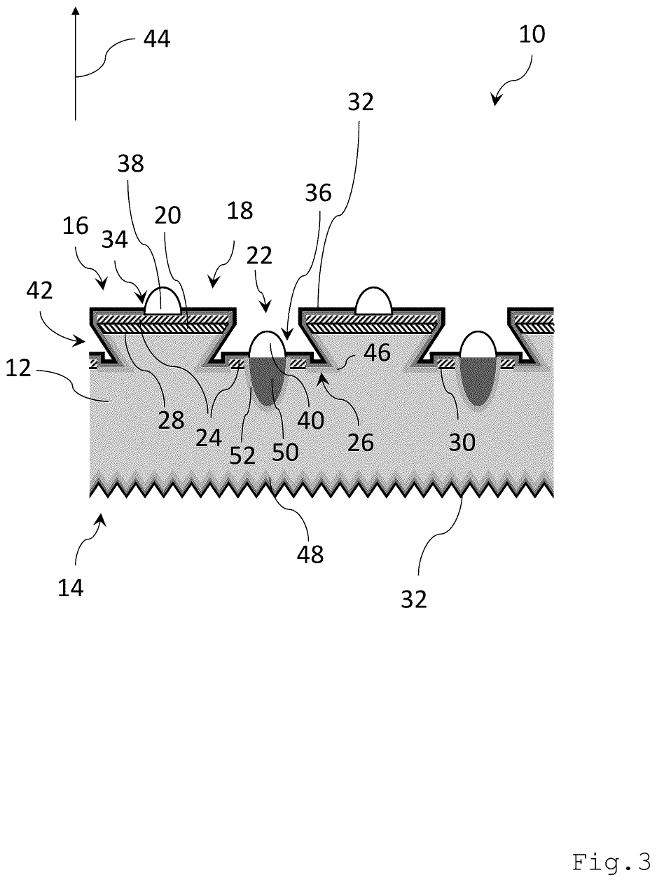

FIG. 3 shows a schematic cross-section of the rear-contact solar cell 10 according to a third embodiment. The third embodiment differs from the second embodiment shown in FIG. 2 in the following ways:

The second electrodes 40 (for example, positive electrodes) are aluminum electrodes, which may form an alloy with one or more underlying materials. In the area of the second interruptions 36 in the dielectric layer 32, there is an aluminum-silicon eutectic 50 that breaks through or penetrates the second conductive layer 24 and the second tunneling layer 30. The aluminum-silicon eutectic 50 is at (or under) the second electrodes 40. The aluminum-silicon eutectic 50 may be at least partially surrounded by a fifth conductive layer 52. The fifth conductive layer 52 can be a doped silicon layer. In other words, the silicon around the eutectic 50 is doped. The dopant in the fifth conductive layer 52 can be or comprise aluminum. In the example with an n-type silicon-based semiconductor substrate 12, an aluminum-doped emitter is formed that surrounds the eutectic 50. In another embodiment with a p-type semiconductor substrate 12, an aluminum-doped back surface field (Al-BSF) 52 can form at or adjacent to the interruptions 36.

It is also conceivable that the first electrodes 38 also form a fifth conductive layer and/or a eutectic. The eutectic of (or below) the first electrodes 38, in particular, may extend only into the second conductive layer 24, and not into the first conductive layer 20 or below. The fifth conductive layers and/or eutectics of or below the first electrodes 38 and the fifth conductive layers of the eutectics of or below the second electrodes 40 may have opposite polarities. The doping type of the respective eutectics may correspond to the polarity of the respective first and second electrodes 38, 40 or according to the respective first and/or second conductive layers 20, 24. It is also conceivable that the aluminum electrodes described above are present in combination with the first embodiment of the solar cell according to FIG. 1.

The semiconductor substrate 12, the first conductive layers 20, the second conductive layers 24, the third conductive layers 46, the fourth conductive layer 48, and/or the third areas 26 of the solar cell 10 according to one of the three embodiments described above may each have a doping according to one of the combinations in Table 2 below.

TABLE 2

| | | | | Front side |
|---|---|---|---|---|
| | | | | 14 of the |
| | | | | solar cell 10 |
| | | Second | Third area 26 | or fourth |
| Semiconductor | First upper | upper | or third upper | conductive |
| substrate 12 | layer 20 | layer 24 | layer 46 | layer 48 |
| n | n | p | — | p |
| n | n | p | — | n |
| n | n | p | p | p |
| n | n | p | n | n |
| n | p | n | — | p |
| n | p | n | — | n |
| n | p | n | p | p |
| n | p | n | n | n |
| p | n | p | — | p |
| p | n | p | — | n |
| p | n | p | p | p |
| p | n | p | n | n |
| p | p | n | — | p |
| p | p | n | — | n |
| p | p | n | p | p |
| p | p | n | n | n |
| p | n | p | — | — |
| p | n | p | — | — |
| p | n | p | p | — |
| p | n | p | n | — |
| p | p | n | — | — |
| p | p | n | — | — |
| p | p | n | p | — |
| p | p | n | n | — |
| n | n | p | — | — |
| n | n | p | — | — |
| n | n | p | p | — |
| n | n | p | n | — |
| n | p | n | — | — |
| n | p | n | — | — |
| n | p | n | p | — |
| n | p | n | n | — |

FIG. 4 shows a scanning electron microscope image of first, second, and third areas 18, 22, 26 of the solar cell 10. This can be a solar cell 10 according to one of the three embodiments described above. The third areas 26 are produced by an under-etching process. The regions 27 and 29 are each inclined. The pedestal-like elevations 42 do not have a fully widening cross-section. In versions with a widening cross-section, at least a partial area (regardless of how small) can be formed with under-etching (e.g., with a widening cross-section).

In a unidirectional, directed deposition (e.g., physical vapor deposition), material is deposited only on a free or exposed surface, thus outside the third region 26 (the underetched area). The third region 26 therefore leads to an interruption in a unidirectionally deposited layer (e.g., the second conductive layer 24, not shown in FIG. 4).

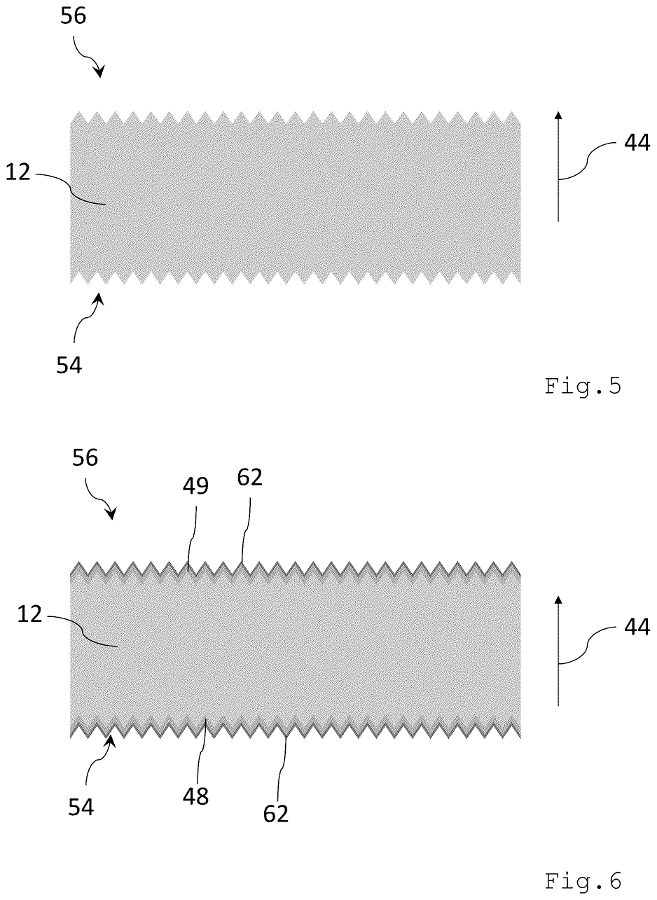

FIGS. 5 to 16 show a method for producing a rear-contact solar cell 10 according to one or more embodiments. The method illustrated can be used to produce the solar cell 10 according to the above descriptions, in particular according to the first embodiment shown in FIG. 1.

FIG. 5 shows a semiconductor substrate 12 (or silicon wafer) having a front side 54 and a back side 56. The front side 54 of the semiconductor substrate 12 corresponds particularly to the front side 14 of the solar cell 10. Accordingly, the back side 56 of the semiconductor substrate 12 corresponds to the back side 16 of the solar cell 10. The first direction 44 is oriented perpendicularly to the front side 54 and the back side 56, and in one example, is directed away from the back side 56. The deposition direction of the second conductive layer 24 by PVD is opposite to the first direction 44 in the one example. In other words, the deposition direction of the second conductive layer 24 is oriented opposite to the first direction 44 in the one example.

Initially, the semiconductor substrate 12 can be textured by isotropic etching, and more preferably on the front side 54 and the back side 56. An additional etching before texturing to remove saw damage is possible. Other methods of texturing are also conceivable.

The semiconductor substrate 12 can undergo a full-area diffusion, for example, a furnace or oven diffusion, to dope the surfaces, and more preferably the front side 54 and back side 56. It can be doped either with a p-type or n-type dopant, such as boron or phosphorus. This allows for the formation of the fourth conductive layer 48 on the front side 14 of the solar cell 10. Depending on the doping, the dopant forms a so-called “Front Floating Emitter” or a “Front Surface Field.” On the back side 56 of the semiconductor substrate 12, a dopant can also diffuse to the surface, creating an undesirable doping layer 49 (see FIG. 6).

During the diffusion (e.g., conducted in the presence of oxygen or air), a dopant-rich silica glass, such as a borosilicate glass (BSG) or a phosphosilicate glass (PSG), can form and/or grow on exposed surfaces of the semiconductor substrate 12. This results in the formation of a silicate glass layer 62 on both the front side 54 and the back side 56 of the semiconductor substrate 12 (see, e.g., FIG. 6). On the back side 56 of the semiconductor substrate 12, the doping layer 49 and the silicate glass layer 62 are undesirable and should be at least partially or completely suppressed or completely removed. Particularly for a solar cell 10 with a p-type semiconductor substrate 12, this diffusion step can also be skipped, so that the doping on the front side 54 of the semiconductor substrate 12 (or on the front side 14 of the solar cell 10) is not higher than the base doping of the semiconductor substrate 12. It is equally conceivable that the front side 14 of the solar cell 10 and/or the front side 54 of the semiconductor substrate 12 can be undoped.

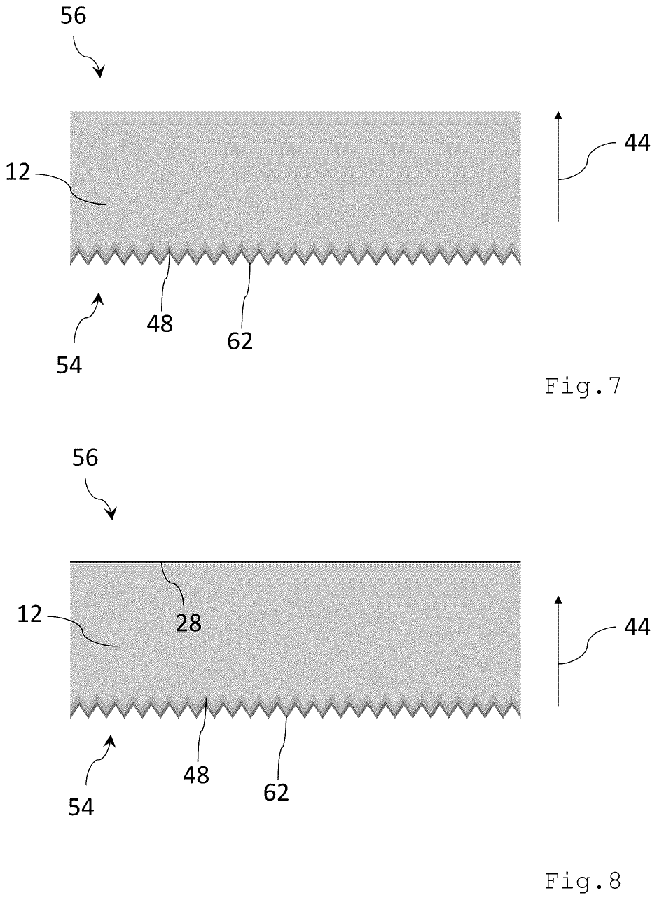

FIG. 7 shows the structure after performing wet chemical etching on the back side 56 of the semiconductor substrate 12. This removes the dopant layer 49 and the silicate glass layer 62. Accordingly, if the back side 56 does not have the dopant layer 49 or the silicate glass layer 62 thereon, then the back side 56 of the semiconductor substrate 12 does not need to be wet chemical etched. However, if present, the silicate glass layer 62 on the back side 56 can, for example, initially be etched in an acidic wet etching solution in which only the back side 56 is immersed in or exposed to the acidic solution (e.g., a single-sided wet chemical etch). A further alkaline etching process etches the exposed back side 56 of the silicon wafer 12 and removes the dopant layer 49. The silicate glass layer 62 on the front side 54 of the semiconductor substrate 12 prevents the etching of the fourth conductive layer 48 in the alkaline etching process. Advantageously, the etching is anisotropic, so that a planar surface is formed on the back side 56 of the semiconductor substrate 12. An isotropic etching for a still-textured back side 56 of the semiconductor substrate 12 is also conceivable.

Next, the first tunneling layer 28 is formed on the back 56 of the semiconductor substrate 12 (see FIG. 8). This can be grown thermally or deposited (e.g., by CVD or PVD). The thickness of the first tunneling layer 28 can range from 5 to 200 Angstroms. The first tunneling layer 28 may be or comprise a silicon oxide (e.g., silicon dioxide). Other dielectric materials that can serve for surface passivation are also conceivable, provided they allow for the passage of charge carriers. Hydrogenated intrinsic amorphous silicon (a-Si:H), or comparable materials, for application in heterojunction solar cells are also possible. The first tunneling layer 28 may, if necessary, also be grown or deposited on the front side 54. However, deposition on the front side 54 has no or only an insignificant influence on the further process and is therefore not considered further.

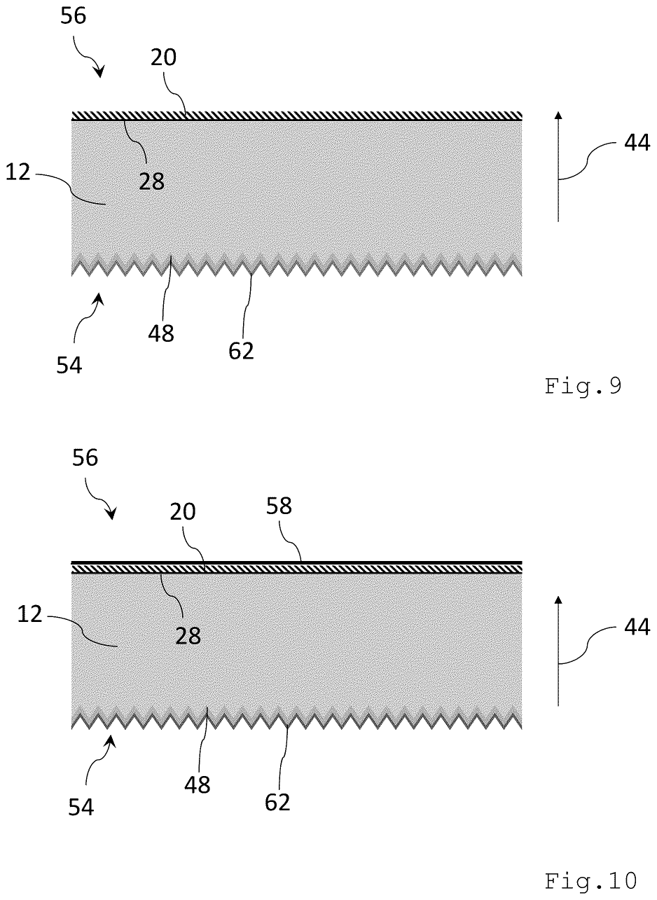

On the first tunneling layer 28, the first conductive layer 20 is subsequently formed (see FIG. 9), for example by deposition. The thickness of the first conductive layer 20 can be between 20 nm and 400 nm. The first conductive layer 20 may have a dopant concentration in a range of 1×10¹⁹ cm⁻³ to 3×10²¹ cm⁻³. The deposition of the first conductive layer 20 can be carried out, for example, using PVD, LPCVD, PECVD, or APCVD. The first conductive layer 20 may also be deposited, at least partially at the edges, on the front side 54 of the semiconductor substrate 12. The first conductive layer 20 can be doped in-situ during deposition, or initially deposited intrinsically and then doped ex-situ, for instance, via a furnace diffusion. In the case of ex-situ doping, the silicate glass layer 62 on the front side 54 may serve at least partially as a diffusion barrier, especially when the doping types of the first conductive layer 20 and the fourth conductive layer 48 are opposite. If the first conductive layer 20 is also deposited on the front side 54, it may be removed and/or processed in further steps of the method.

Next, an etch-stable barrier layer 58 is formed on the first conductive layer 20 (see FIG. 10), for example by deposition. The barrier layer 58 can, for example, be or comprise silicon nitride (SiNₓ), silicon oxide (SiOₓ), and/or silicon oxynitride (SiOₓN_{y}) as described herein. The barrier layer 58 can also comprise a stack of layers on the back side 56 of the semiconductor substrate 12. The barrier layer 58 serves as an etch barrier against an alkaline etch in a subsequent process step. In the case of ex-situ doping of the first conductive layer 20, the silica glass grown or formed during furnace diffusion can also be used as an etch-stable barrier layer 58. The barrier layer 58 may also completely or partially cover the front side 54, for example at the edges. The possible barrier layer 58 on the front side 54 is not shown, but can be taken into account or removed in further processing steps, if necessary or desired.

After the etch-stable barrier layer 58 has been formed, it is removed in a plurality of etching areas 60 (see FIG. 11), for example, by laser ablation. The ablation width can range from 50 μm to 2000 μm. The distance (center to center) between two adjacent etching areas 60 can be between 200 μm and 3000 μm. The ablation can be linear, leading to a so-called “interdigitated” pattern. This pattern may be interrupted in areas in which busbars for the solar cell 10 are to be formed. When removing the barrier layer 58 in the etching areas 60, the first conductive layer 20 can be partially or completely removed, and if completely removed, the first tunneling layer 28 can also be partially or completely removed. Additionally, if both the first conductive layer 20 and the first tunneling layer 28 are completely removed, the exposed semiconductor substrate 12 can be partially removed at or from the back side 56.

Subsequently, the etching areas 60 are etched, during which the pedestal-like elevations 42 of the semiconductor substrate 12 are created (see FIG. 12). The first areas 18 are on the elevations 42, and the second areas 22 are between the elevations 42. In particular, the first conductive layer 20, the first tunneling layer 28, and partially the semiconductor substrate 12 at the back side 56 are removed in the second areas 22 by etching in the etching areas 60. The etching can be performed using an acidic or alkaline solution that removes silicon isotropically or anisotropically (preferably at least partially isotropically). The etch-stable barrier layer 58 (outside the etching areas 60) is not etched or etched only very slowly, so that outside the etching areas 60, there is no or only minimal etching of the first conductive layer 20 immediately under the etch-stable barrier layer 58 (e.g., in a direction perpendicular to the first direction 44). The etch-stable barrier layer 58, the first conductive layer 20, and the first tunneling layer 28 are undercut while etching the etching areas 60, creating the third areas 26, which are shaded along the first direction 44 (vertically) by the etch-stable barrier layer 58, the first conductive layer 20, the first tunneling layer 28, and the semiconductor substrate 12. The depth of the etch areas 60 is determined by the etch rate and the etching time, and can range from 0.5 μm to 20 μm.

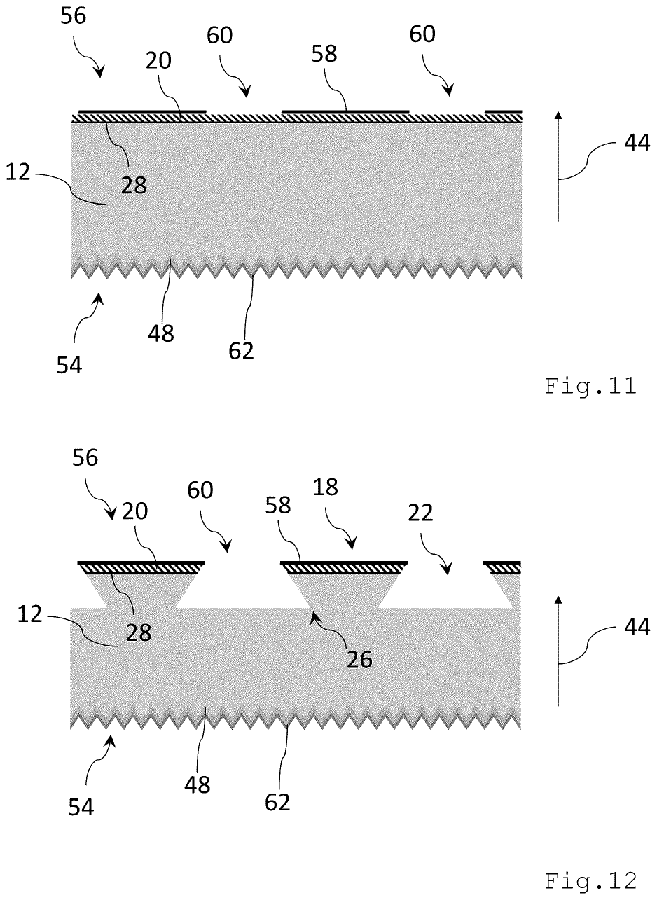

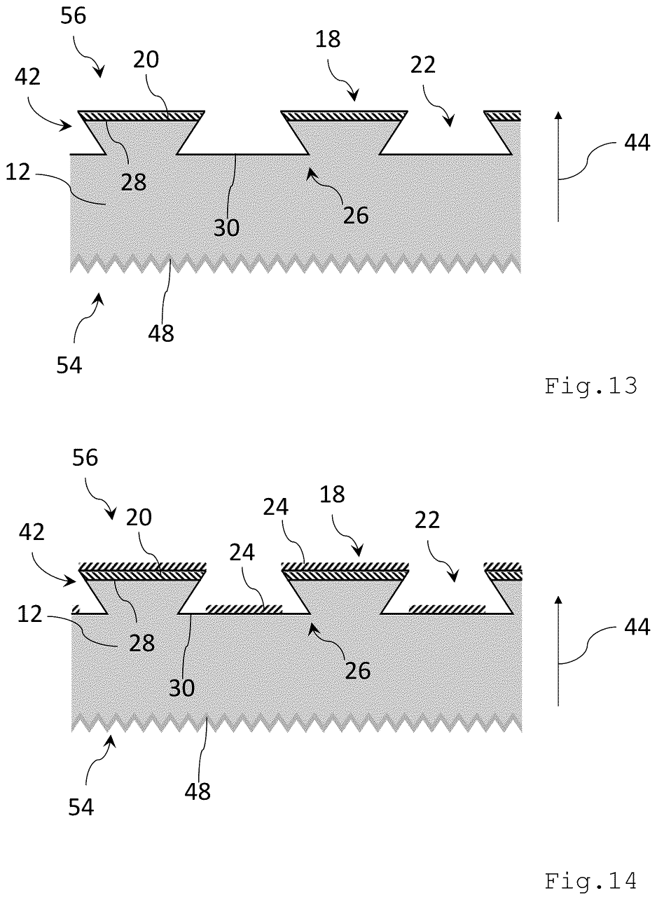

The etching areas 60 are etched only on the back side 56, in a single-sided etching process. In one example of a batch etching process in which the semiconductor substrate 12 (e.g., silicon wafer) is completely immersed in the etchant (i.e., both the front side 54 and back side 56 are exposed or immersed in the etchant), the silicate glass layer 62 on the front side 54 can serve as an etching barrier and prevent the etching of the front side 54 of the semiconductor substrate 12. If, in a previous step, the first conductive layer 20 was also deposited on the front side 54, it can be etched until the underlying etching barrier (i.e., the silicate glass layer 62) is exposed. If the etch-stable barrier layer 58 was also deposited on the front side 54 in a previous step, it can be selectively removed by an (acidic) etchant on the front side 54, for example, in a (subsequent) single-sided etching process. Alternatively, the etch-stable barrier layer 58 on the front side 54 can be removed by complete immersion in the etchant (see, e.g., the discussion of FIG. 13 below). This also applies if an etch-stable silicate glass was grown on the first conductive layer 20 during ex-situ doping.

The etch-stable barrier layer 58 and/or the silicate glass layer 62 can subsequently be completely removed (see FIG. 13), for example, using an acidic etching solution. A cleaning step may follow. In the next step, the second tunneling layer 30 can be formed by deposition or thermal growth (see FIG. 13). The second tunneling layer 30 can be formed on the back side 56. Additionally, the second tunneling layer 30 can also be formed on the front side 54. The second tunneling layer 30 can saturate open bonds at the surface of the semiconductor substrate 12. The second tunneling layer 30 can have a thickness of 5 to 200 Angstroms.

Subsequently, the second conductive layer 24 is formed (see FIG. 14), for example by deposition. The second conductive layer 24 can be deposited using a directional method, for example, PVD. The second conductive layer 24 (e.g., p-type or n-type) has a doping that is preferably opposite to that of the first conductive layer 20 (e.g., n-type or p-type, respectively). Due to the widening cross-section of the pedestal-like elevations 42 in the first direction 44, the second conductive layer 24 is not formed in the third areas 26. Thus, the third areas 26 do not contain any amorphous, partially crystalline, or polycrystalline silicon. Particularly because of the directional deposition (directed parallel and/or counter to the first direction 44), no material of the second conductive layer 24 is deposited in the third areas 26, as they are shaded.

Within the first areas 18, the second conductive layer 24 is deposited on the second tunneling layer 30 and the underlying first conductive layer 20. The thickness of the second conductive layer 24 can range from 20 nm to 400 nm. The second conductive layer 24 may have a dopant concentration between 1×10¹⁹ cm⁻³ and 3×10²¹ cm⁻³. In particular, due to the targeted deposition, the second conductive layer 24 is not deposited on the front side 54. A high-temperature step for crystallizing the first and/or the second conductive layer 20, 24, as well as for activating the dopants in the first and/or the second conductive layer 20, 24, may follow.

It is conceivable that initially a non-doped layer is deposited (optionally also in the third areas 26), and the non-doped layer is then directionally doped, for example by ion implantation, outside of the third areas 26 to form the second conductive layer 24. Furthermore, it is conceivable that a directed deposition can also be implemented in the third areas 26, but to a lesser extent, so that with or without an etching step, the resistance is sufficiently high to not affect the efficiency of the solar cell 10. In heterojunction solar cells, the conductive layer (e.g., the second conductive layer 24) can also include a layer stack with a conductive metal or metal oxide.

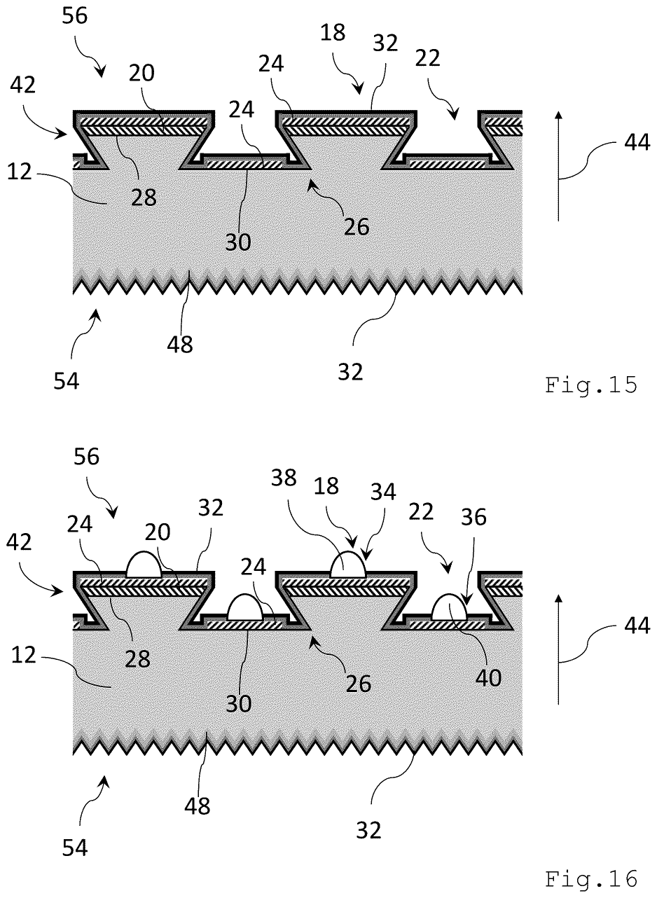

Next, a dielectric layer 32 for passivating the surface of the front side 54 and/or the rear side 56 can be deposited (see FIG. 15). The dielectric layer 32 can comprise one or more layers, for example, aluminum oxide, a silicon oxide (which may be undoped or doped with one or more of boron, phosphorous and fluorine), and/or silicon nitride. The dielectric layer 32 may also comprise two or more layers. The dielectric layer 32 on the front side 54 and/or the dielectric layer 32 on the rear side 56 can be identical or different, and can have different properties. A wet chemical cleaning step may precede the deposition of the dielectric layer 32. Hydrogen in the dielectric layer can serve to saturate open bonds on the surface of the semiconductor substrate 12, especially in the first and second areas 18, 22, where the first or second conductive layer 20, 24 is. The dielectric layer 32 can also serve as an anti-reflective coating, especially on the front side 54, and increase the light yield of the solar cell.

Subsequently, the first and second electrodes 38, 40 can be formed and/or applied (see FIG. 16). The first and/or second electrodes 38, 40 are arranged such that the first electrodes 38 each contact a second conductive layer 24 and the second electrodes 40 each contact a second conductive layer 24.

To contact the electrodes 38, 40, the dielectric layer 32 (if present) can have the first and second interruptions 34, 36 at the respective locations. The implementation of the interruptions 34, 36 can be carried out, for example, by local ablation, such as laser irradiation. The electrodes 38, 40 can also be formed from one or more pastes, in which case the first and second interruptions 34, 36 can be generated while firing (heating) the paste(s), which can locally dissolve the dielectric layer 32. Firing the paste(s) can also positively affect the passivation of the non-metallized surfaces, as the hydrogen contained in the dielectric layer 32 is mobilized during the firing (e.g., at a high temperature), diffuses to the surfaces of the semiconductor substrate 12, and saturates open bonds there.

The first and/or second interruptions 34, 36 can be continuous (e.g., lines) or interrupted (e.g., in the form of round dots, squares, or segmented lines). The pastes may, for example, include silver, copper, or aluminum as a conductive metal. After firing, the conductive particles in the pastes sinter together and form the first and/or second electrodes 38, 40. The first and/or second electrodes 38, 40 may also comprise a stack of layers, for example, silver and copper, and be formed from a paste stack. When using aluminum, the composition of the paste(s) can be chosen so that the aluminum is not or only minimally alloyed with silicon. Such a composition is suitable for electrodes of both polarities.

The composition of an aluminum paste can also be chosen in such a way that during firing, the aluminum alloys with the silicon and the resulting aluminum-silicon eutectic penetrates through the second conductive layer (e.g., at the second interruptions). In this process, the aluminum can further dope the silicon substrate and surround the eutectic, so that, depending on the polarity of the substrate, an Al-doped emitter or an Al-doped back field can form. Such a doping paste is particularly suitable for positive electrodes (see, e.g., FIG. 3). For negative electrodes, an n-type dopant can be added to the paste, so that the paste is suitable for forming the negative electrode, and after the formation of the eutectic, an n-type doped silicon surrounds the eutectic.

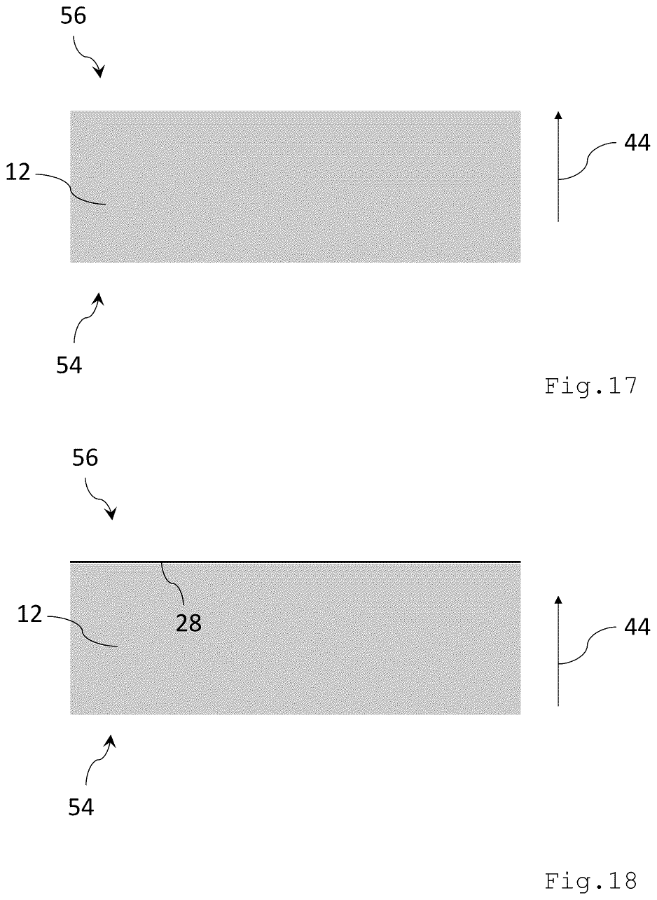

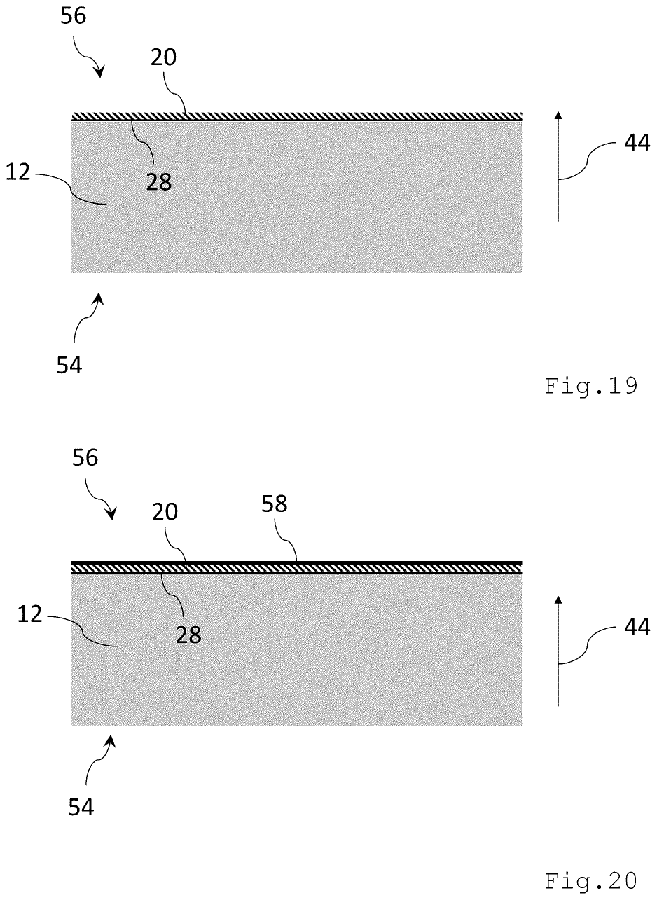

FIGS. 17 to 28 show a method for producing a back-contact solar cell 10 according to a second embodiment. The method illustrated can be used to manufacture the solar cell 10 in accordance with the above descriptions, and more preferably in accordance with the embodiment shown in FIG. 2.

In a first step, the semiconductor substrate 12 is etched anisotropically to remove any sawing damage and create s planar front side 54 and a planar back side 56 of the semiconductor substrate 12 (see FIG. 17).

Next, analogous to the first embodiment of the method, the first tunneling layer 28 is formed, then the first conductive layer 20, and subsequently the barrier layer 58 on the back side 56 of the semiconductor substrate 12 (see FIGS. 18-20). The first tunneling layer 28 may have a thickness of 5 to 200 Angstroms, the first conductive layer 20 a thickness of 20 nm to 400 nm, and the barrier layer 58 may be formed analogously to the first embodiment of the method. The first tunneling layer 28 can also be thermally grown. The first tunneling layer 28, the first conductive layer 20, and/or the barrier layer 58 may completely cover the back side 56 of the semiconductor substrate 12. The first tunneling layer 28, the first conductive layer 20, and/or the barrier layer 58 may each, or all together, completely or partially cover the front side 54 of the semiconductor substrate 12, but preferably, at most only at the edges.

The first conductive layer 20 can be deposited and doped in-situ, at a dopant concentration of 1×10¹⁹ to 3×10²¹ cm⁻³, or initially deposited intrinsically and then doped ex-situ, for example, by furnace diffusion. When a silicate glass grows on the surface during the furnace diffusion, it can be used as a possible barrier layer 58. The doping of the first conductive layer 20 can include either n-type or p-type doping as per Tables 1-2. The barrier layer 23 may comprise a dielectric layer such as SiOₓ, SiOₓN_{y}, or SiNₓ, as described herein or a stack or plurality of (such) layers.

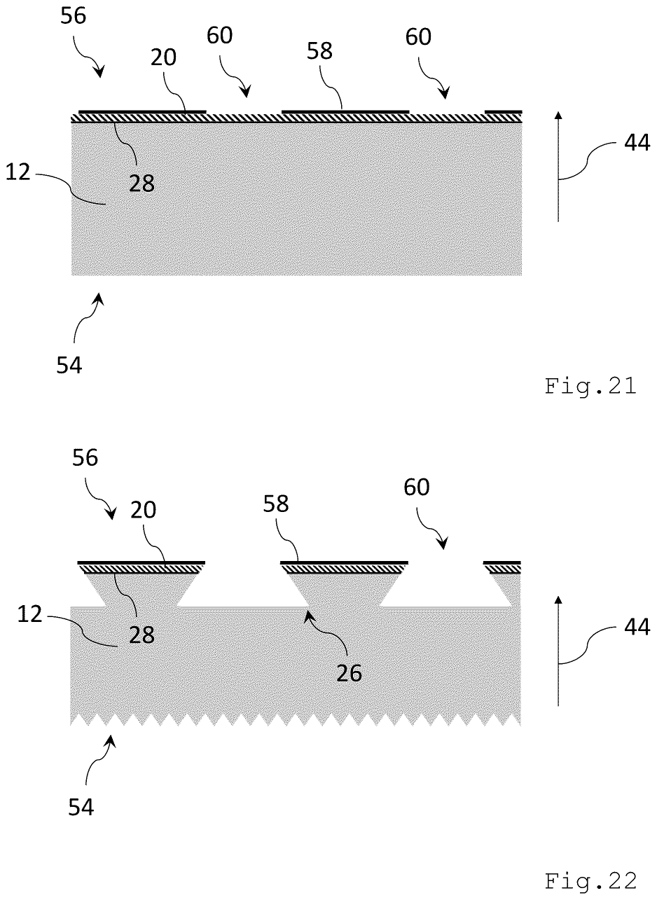

Subsequently, the barrier layer 58 is locally removed, analogous to the first embodiment of the method, to form etching areas 60 (see FIG. 21). This can be implemented, for example, by laser ablation. In this process, the first conductive layer 20, and optionally the first tunneling layer 28, can also be removed partially or completely in the etching areas 60. Furthermore, the semiconductor substrate 12 (on its back side 56) can be removed at least partially in the etching areas 60 when the first conductive layer 20 and the first tunneling layer 28 are completely removed.

Afterward, a wet chemical etching step is performed to remove (if still present) the first conductive layer 20, the first tunneling layer 28, and part of the semiconductor substrate 12 (see FIG. 22). Here, approximately 0.5 μm to 20 μm of the semiconductor substrate 12 can be removed in the etching areas 60. Etching with an alkaline silicon etch can be carried out unilaterally on only the back side 56, or may also include the front side 54. In this case, the layers that may have been deposited on the front side 54 in the preceding process steps should also be etched, if necessary with an additional unilateral or single-sided etch.

It is also conceivable to clean and/or etch the front side 54 in an earlier or later process step. Etching the front side 54 can create a textured surface on the front side 54. It is important that when etching on the back side 56, regions of the first conductive layer 20, the first tunneling layer 28, and the semiconductor substrate 12 below a peripheral edge or region of the barrier layer 58 are underetched so that the elevations 42 and the third areas 26 are formed. The third (underetched) areas 26 are shaded along the first direction 44 (perpendicular to the surface of the back side 56) by the barrier layer 58 and the first conductive layer 20. Regardless of whether isotropic or anisotropic etching is used, etchant(s) and etching conditions are selected so that the third (underetched) areas 26 are formed. Particularly in the case of isotropic etching, the surface of the third areas 26 can be textured and provided with an inclination (e.g., a non-zero or non-90° angle relative to the first direction 44 or a planar surface of the semiconductor substrate 12), as shown in FIGS. 1-4.

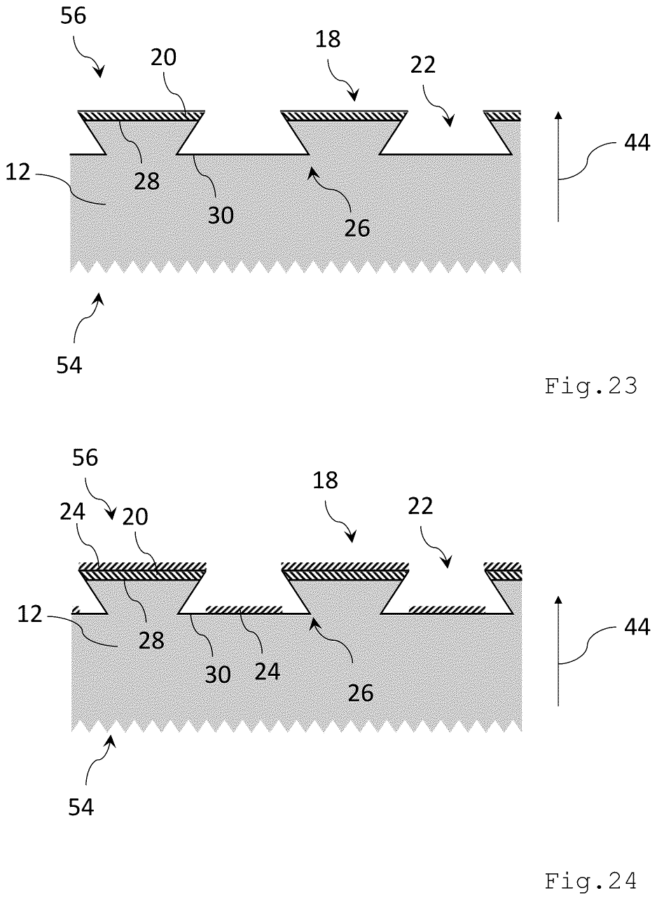

After etching, the second tunneling layer 30 is formed by thermal growth or deposition (see FIG. 23). The second tunneling layer 30 can have a thickness of 5 to 200 Angstroms. The second tunneling layer 30 can be grown or deposited in a non-directional manner, allowing it to also be formed in the first, second, and third areas 18, 22, 26. The second tunneling layer 30 can also be formed on the front side 54.

Afterwards, the second conductive layer 24 is formed (see FIG. 24), for example by directed deposition (physical vapor deposition [PVD]). In this process, the second conductive layer 24 is deposited over the entire unshaded surface on the back side 56 of the semiconductor substrate 12. In the undercut, shaded third areas 26, the second conductive layer 24 is not deposited. Thus, the second conductive layer 24 is interrupted in the third areas 26. Within the second areas 22, the second conductive layer 24 is also not in contact with the first conductive layer 20.

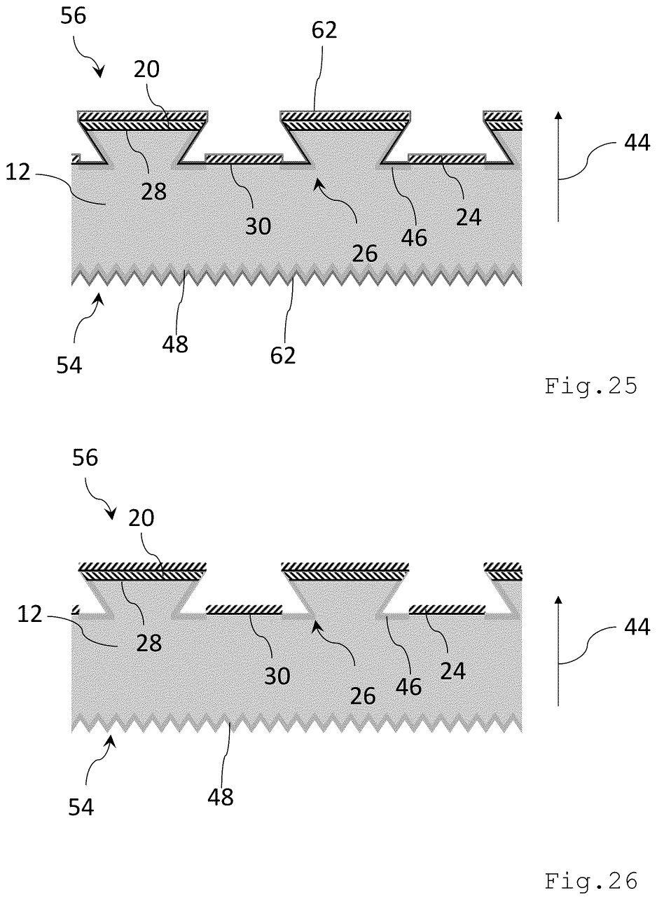

The second conductive layer 24 can either be deposited and doped in situ or deposited intrinsically and then doped, for example, in an oven diffusion (see FIG. 25). A further layer can be deposited on the second conductive layer 24 by PVD, which can serve as a diffusion barrier in a subsequent (oven) diffusion step. This can prevent further doping of the second conductive layer 24 during an oven diffusion. In addition, a third conductive layer 46 having a doping type opposite to that of the second conductive layer 24 can be formed in the third (substrate) areas 26. The doping type of the second conductive layer 24 should, according to Tables 1-2, be the opposite of the first conductive layer 20. For the preparation of a charge carrier-selective contact, a high-temperature step may be used that crystallizes an amorphous, partially crystalline or polycrystalline silicon first conductive layer 20 and/or second conductive layer 24 and activates the dopants therein. This crystallization can, for example, also occur in the oven diffusion step described above, thereby avoiding the aforementioned high-temperature step.

FIG. 25 shows such a process in which a dopant, e.g., boron or phosphorus, is diffused into the semiconductor substrate 12 through the front side 54 to form a fourth conductive layer 48. The polarity of the dopant for the fourth conductive layer 48 is to be chosen according to Tables 1-2. It may prove to be advantageous if the back side 56 is also doped completely or at least partially in the same process step. In particular, the same or a similar doping process (e.g., dopant type, dose, conditions) can be performed on both the third areas 26 and the front side 54 of the substrate 12. In other words, the third conductive layer 46 can be formed simultaneously with the fourth conductive layer 48. The second conductive layer 24 can also be doped during this diffusion step if the second conductive layer 24 was deposited intrinsically, or be further doped if the second conductive layer 24 is not covered by a diffusion barrier.

The dopant concentration in the second conductive layer 24 may differ from the dopant concentration in the third areas 26 and the dopant concentration of the fourth conductive layer 48, as the diffusion rate in amorphous, partially crystalline, or polycrystalline silicon is higher than in the monocrystalline semiconductor substrate 12. Furthermore, the second tunneling layer 30 may prevent or reduce diffusion in the third areas 26 and on the front side 54, as long as the second tunneling layer 30 is present there.

On the front side 54 and the back side 56, during the diffusion step, and more preferably in the case of oven diffusion, a silicate glass layer 62, e.g., a borosilicate glass (BSG) or a phosphosilicate glass (PSG), can be formed or grown (see FIG. 25). The process step depicted in FIG. 25 can be omitted, especially for a p-type semiconductor substrate 12, so that no conductive layer having a higher dopant concentration than the semiconductor substrate 12 (such as the fourth conductive layer 48) is formed on the front side 54 or in the third areas 26. Thus, the third conductive layer 46 can be omitted. In this case, the second conductive layer 24 can be deposited and doped in-situ.

In a further step, an etching or wet chemical cleaning process can be performed to remove the silicate glass layer 62 on the front side 54 and the back side 56 (see FIG. 26). The second tunneling layer 30 in the third areas 26 (when present) can also be removed in the same wet chemical cleaning or etching process as the silicate glass layer 62. In other words, the second tunneling layer 30 (when present) and the silicate glass layer 62 can be removed together, in the same process.

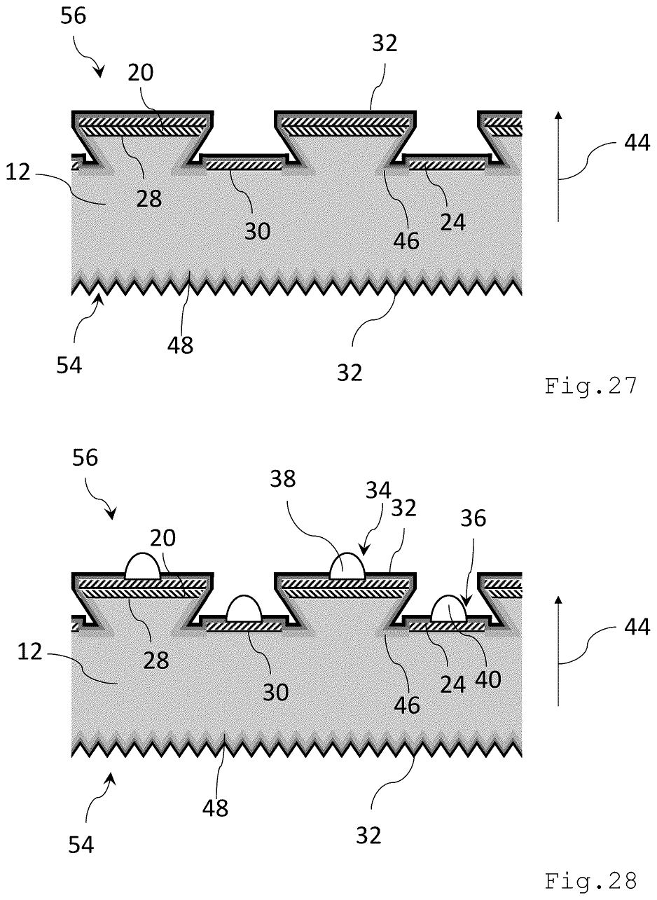

FIGS. 27 and 28 illustrate the formation of the dielectric layer 32 on the front side 54 and the back side 56, as well as the formation of the first and second electrodes 38, 40. The dielectric layer 32 on each of the front side 54 and the back side 56 may comprise or consist of two (dielectric) layers. The steps shown in FIGS. 27 and 28 correspond to the steps of the first embodiment shown in FIGS. 15 and 16 and are performed identically or substantially identically.

The individual steps of the two above-described embodiments of the method can be freely combined and/or supplemented with each other.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

1. A back side contact solar cell comprising a semiconductor substrate having a front side and a back side, wherein the back side includes:
a plurality of first areas on pedestal-like elevations of the semiconductor substrate, wherein each of the plurality of first areas has a first tunneling layer and a stack comprising a first conducting layer and a second conducting layer, the first tunneling layer is between the first conducting layer and the semiconductor substrate, the first conducting layer and the second conducting layer are each amorphous, polycrystalline or partially crystalline, and each of the elevations has a cross-section that widens at least partially in a first direction,
a plurality of second areas each having the second conducting layer and a second tunneling layer between the second conducting layer and the semiconductor substrate,
a plurality of third areas, wherein the third areas do not contain amorphous, polycrystalline or partially crystalline silicon,
a first dielectric layer or a first dielectric layer stack at least partially covering a surface of the back side, wherein the first dielectric layer or the first dielectric layer stack includes a first interruption in the first areas and a second interruption in the second areas,
a plurality of first electrodes, each contacting a unique one of the second conducting layers in the first areas through a corresponding one of the first interruptions, and
a plurality of second electrodes, each contacting a different unique one of the second conducting layers in the second areas through a corresponding one of the second interruptions.

2. The back-contact solar cell according to claim 1, wherein said third areas are undercut areas.

3. The back-contact solar cell according to claim 1, wherein the third areas are undoped.

4. The back-contact solar cell according to claim 1, wherein each of the third areas has a third conductive layer.

5. The back-contact solar cell according to claim 1, further comprising a fourth conductive layer on the front side.

6. The back-contact solar cell according to claim 1, wherein the first conductive layers have a first doping type and the second conductive layers have a second doping type opposite from the first doping type.

7. The back-contact solar cell according to claim 6, wherein the semiconductor substrate has the first doping type.

8. The back-contact solar cell according to claim 6, wherein the semiconductor substrate has the second doping type.

9. The back-contact solar cell according to claim 1, wherein each of the first conductive layers, the second conductive layers, the first tunneling layers, and/or the second tunneling layers is free of openings.

10. The back-contact solar cell according to claim 1, further comprising a plurality of aluminum-silicon eutectics at each of the first electrodes and/or the second electrodes, penetrating underlying ones of the second conductive layers and/or the second tunneling layers.

11. The back-contact solar cell according to claim 10, further comprising a fifth conductive layer at least partially surrounding each of the aluminum-silicon eutectics, wherein the fifth conductive layer has a doping type corresponding to a doping of the first conductive layer or the second conductive layer.

12. The back-contact solar cell according to claim 1, further comprising a second dielectric layer or a second dielectric layer stack at least partially covering a surface of the front side.

13. A method for producing a rear-contact solar cell, comprising:
forming a first tunneling layer on a back side of a semiconductor substrate;
forming a first conductive layer having a first polarity on the first tunneling layer;
forming an etch-stable barrier layer on the first conductive layer;
removing the etch-stable barrier layer in a plurality of etch areas;
etching the plurality of etch areas to form pedestal-like elevations of the semiconductor substrate, each of the elevations having a cross-section widening in a first direction;
forming a second tunneling layer in areas between the pedestal-like elevations of the semiconductor substrate;
forming a second conductive layer with a second polarity in each of the areas between the pedestal-like elevations, wherein the second polarity is opposite to the first polarity, and no or a minimal second conductive layer forms in areas under widening parts of the pedestal-like elevations.

14. The method of claim 13, wherein removing the etch-stable barrier layer exposes the first conductive layer in each of the plurality of etch areas, and etching the plurality of etch areas etches the first conductive layer, the first tunneling layer and part of the semiconductor substrate in each of the plurality of etch areas.

15. The method of claim 13, further comprising completely removing the etch-stable barrier layer.

16. The method of claim 13, further comprising forming third conductive layers in the areas under widening parts of the pedestal-like elevations.

17. The method of claim 13, further comprising forming a fourth conductive layer at or in a front side of the semiconductor substrate by thermal diffusion.

18. The method of claim 17, further comprising forming a silicate glass layer during the thermal diffusion, then removing the silicate glass layer.

19. The method of claim 13, further comprising forming first electrodes on or over the first conductive layer on the pedestal-like elevations and second electrodes on the second conductive layers.

20. The method of claim 19, further comprising forming an aluminum-silicon eutectic on the second electrodes using a paste or a paste stack, wherein the paste or the paste stack contains a p-type dopant or an n-type dopant.
